(19) United States
(12) Patent Application Publication
(10) Pub. No.: US 2025/0365988 A1
(43) Pub. Date: Nov. 27, 2025

(54) SEMICONDUCTOR MEMORY DEVICE

(71) Applicant: SAMSUNG ELECTRONICS CO., LTD., Suwon-si (KR)

(72) Inventors: Youngseok Park, Suwon-si (KR); Changsik Yoo, Suwon-si (KR); Kyuchang Kang, Suwon-si (KR); Sangyun Kim, Suwon-si (KR); Younghun Seo, Suwon-si (KR); Hyunchul Yoon, Suwon-si (KR)

(73) Assignee: SAMSUNG ELECTRONICS CO., LTD., Suwon-si (KR)

(21) Appl. No.: 19/007,250

(22) Filed: Dec. 31, 2024

(30) Foreign Application Priority Data
May 23, 2024 (KR) 10-2024-0067298

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08145; H01L 2924/1431; H01L 2924/1436

(57) ABSTRACT

Provided is a semiconductor memory device including: a first layer including a first sub-cell array including memory cells; a second layer including a second sub-cell array; and a third layer including sub-wordline drivers and sense amplifiers, wherein the first, second, and third layers are stacked in a first direction perpendicular to the first layer, wherein the first layer includes first wordlines and first bitlines extending in the direction perpendicular to the first direction, wherein the second layer includes second wordlines and second bitlines extending in the direction perpendicular to the first direction, wherein the first wordlines are connected to the second wordlines in the first direction, wherein each of the first wordlines is connected to one of the sub-wordline drivers, wherein the first bitlines are connected to the second bitlines in the first direction, and wherein each of the first bitlines is connected to one of the sense amplifiers.

### CROSS-REFERENCE TO RELATED APPLICATION

This application is based on and claims priority to Korean Patent Application No. 10-2024-0067298 filed on May 23, 2024, in the Korean Intellectual Property Office, the disclosure of which is incorporated herein by reference in its entirety.

### BACKGROUND

### 1. Field

The present disclosure relates to a semiconductor memory device.

### 2. Description of Related Art

A semiconductor memory device may correspond to a volatile memory device in which stored data is eliminated when a power supply is cut off, and may further correspond to a dynamic random access memory (DRAM), for example. A semiconductor memory device may include a plurality of sub-cell arrays, and the plurality of sub-cell arrays may include memory cells arranged in a matrix form. As it is desirable for electronic product to have a reduced size, multifunctionality, and high-performance, a semiconductor memory device having improved integration density may be required.

### SUMMARY

An example embodiment of the present disclosure is provided to improve integration density of a dynamic random access memory by isolating a plurality of memory cells in a plurality of semiconductor layers, stacking the plurality of semiconductor layers in the vertical direction, connecting the plurality of wordlines included in each of the plurality of semiconductor layers to each other in the vertical direction, and connecting the plurality of bitlines to each other in the vertical direction.

According to an aspect of the disclosure, a semiconductor memory device includes: a first semiconductor layer including at least one first sub-cell array, the at least one first sub-cell array including a plurality of memory cells; a second semiconductor layer including at least one second sub-cell array; and a third semiconductor layer including a plurality of sub-wordline drivers and a plurality of sense amplifiers, wherein the first, the second, and the third semiconductor layers are stacked in a first direction perpendicular to an upper surface of the first semiconductor layer, wherein the first semiconductor layer includes a plurality of first wordlines extending in a direction perpendicular to the first direction and a plurality of first bitlines extending in the direction perpendicular to the first direction, wherein the second semiconductor layer includes a plurality of second wordlines extending in the direction perpendicular to the first direction and a plurality of second bitlines extending in the direction perpendicular to the first direction, wherein the plurality of first wordlines are connected to the plurality of second wordlines in the first direction, wherein each of the plurality of first wordlines is connected to one of the plurality of sub-wordline drivers, wherein the plurality of first bitlines are connected to the plurality of second bitlines in the first direction, and wherein each of the plurality of first bitlines is connected to one of the plurality of sense amplifiers.

According to an aspect of the disclosure, a semiconductor memory device includes: a first region including a plurality of first sub-cell arrays; a second region including a plurality of second sub-cell arrays; and a third region including a plurality of third sub-regions, wherein each of the plurality of third sub-regions includes: a sub-wordline driver region including a plurality of sub-wordline drivers; and a sense amplifier region including a plurality of sense amplifiers, wherein the first, the second, and the third regions are stacked in a first direction, wherein each of the plurality of first sub-cell arrays includes a plurality of first wordlines extending in a second direction perpendicular to the first direction and a plurality of first bitlines extending in a third direction perpendicular to the first direction and the second direction, wherein each of the plurality of second sub-cell arrays includes a plurality of second wordlines extending in the second direction and a plurality of second bitlines extending in the third direction, wherein, for each first sub-cell array of the plurality of first sub-cell arrays, the plurality of first wordlines are connected in the first direction to the plurality of second wordlines of a second sub-cell array among the plurality of second sub-cell arrays, wherein, for each first sub-cell array of the plurality of first sub-cell arrays, the plurality of first wordlines are connected to the sub-wordline driver region of a third sub-region among the plurality of third sub-regions, wherein, for each first sub-cell array of the plurality of first sub-cell arrays, the plurality of first bitlines are connected in the first direction to the plurality of second bitlines of a second sub-cell array among the plurality of second sub-cell arrays, and wherein, for each first sub-cell array of the plurality of first sub-cell arrays, the plurality of first bitlines are connected to the sense amplifier region of a third sub-region among the plurality of third sub-regions.

According to an aspect of the disclosure, a semiconductor memory device includes: a first semiconductor layer including a plurality of first wordlines and a plurality of first bitlines; a second semiconductor layer including a plurality of second wordlines and a plurality of second bitlines; a third semiconductor layer including a plurality of sub-wordline drivers and a plurality of sense amplifiers; a plurality of interconnection patterns extending in a first direction perpendicular to an upper surface of the first semiconductor layer; and a plurality of bonding pads on an upper surface or a lower surface of one of the first, the second, and the third semiconductor layers, wherein the first, the second, and the third semiconductor layers are stacked in the first direction and are coupled to each other by the plurality of bonding pads, wherein the plurality of first wordlines and the plurality of second wordlines extend in a second direction parallel to the upper surface of the first semiconductor layer and perpendicular to the first direction, wherein the plurality of first bitlines and the plurality of second bitlines extend in a third direction parallel to the upper surface of the first semiconductor layer and perpendicular to the second direction, wherein the plurality of interconnection patterns and the plurality of bonding pads connect the plurality of first wordlines to the plurality of second wordlines in the first direction, and to the plurality of sub-wordline drivers, and wherein the plurality of interconnection patterns and the plurality of bonding pads connect the plurality of first bitlines to the plurality of second bitlines in the first direction, and to the plurality of sense amplifiers.

### BRIEF DESCRIPTION OF DRAWINGS

The above and other aspects and features of certain embodiments of the present disclosure will be more apparent from the following description taken in conjunction with the accompanying drawings, in which:

FIG. 1 is a block diagram illustrating a system according to an example embodiment of the present disclosure;

FIG. 2 is a block diagram illustrating a memory system according to one or more embodiments of the present disclosure;

FIG. 3 is a block diagram illustrating the configuration of a semiconductor memory device according to example embodiments of the present disclosure;

FIGS. 4 and 5 are diagrams illustrating a plurality of semiconductor layers of a semiconductor memory device according to example embodiments of the present disclosure;

FIGS. 6 and 7 are diagrams illustrating the plurality of semiconductor layers of a semiconductor memory device according to example embodiments of the present disclosure;

FIGS. 8 and 9 are diagrams illustrating a layout of a semiconductor memory device according to example embodiments of the present disclosure;

FIG. 10 is a plan diagram illustrating a semiconductor memory device according to one or more embodiments of the present disclosure;

FIG. 11 is a cross-sectional diagram illustrating a cross-sectional surface of the semiconductor memory device illustrated in FIG. 10 in A-A′ direction;

FIG. 12 is a cross-sectional diagram illustrating a cross-sectional surface of the semiconductor memory device illustrated in FIG. 10 in B-B′ direction;

FIG. 13 is a cross-sectional diagram illustrating a cross-sectional surface of the semiconductor memory device illustrated in FIG. 10 in C-C′ direction;

FIG. 14 is a diagram illustrating a semiconductor memory device including a demultiplexer according to one or more embodiments of the present disclosure;

FIG. 15 is a diagram illustrating a semiconductor memory device according to one or more embodiments of the present disclosure; and

FIG. 16 is a diagram illustrating an example in which a semiconductor memory device is applied to a mobile system according to one or more embodiments of the present disclosure.

### DETAILED DESCRIPTION

Hereinafter, embodiments of the present disclosure will be described as follows with reference to the accompanying drawings.

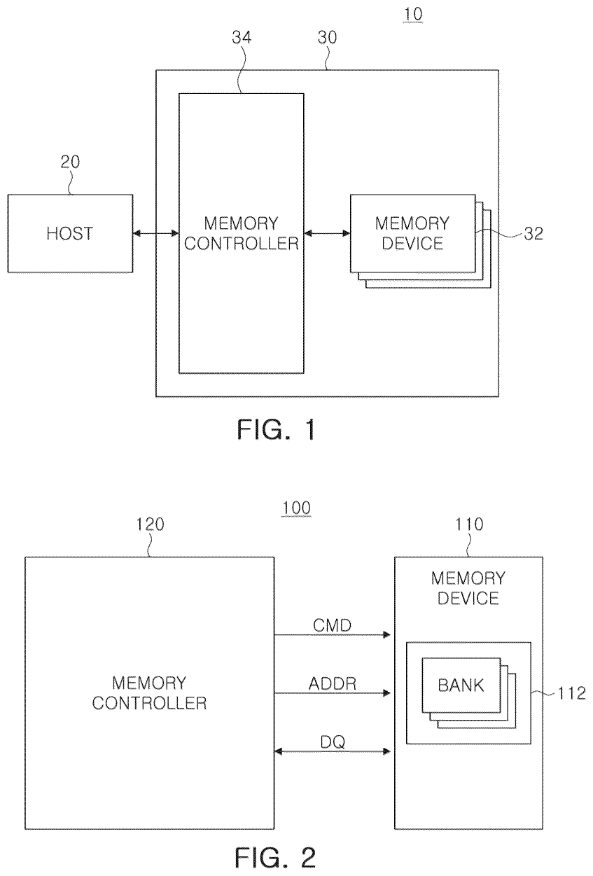

FIG. 1 is a block diagram illustrating a system according to one or more embodiments.

Referring to FIG. 1, a system 10 may include a host 20 and a memory system 30. The memory system 30 may include a plurality of semiconductor memory devices 32, and a memory controller 34.

The host 20 may communicate with the memory system 30 using an interface protocol, such as peripheral component interconnect-express (PCI-E), advanced technology attachment (ATA), serial ATA (SATA), parallel ATA (PATA), or serial attached SCSI (SAS). Also, interface protocols between the host 20 and the memory system 30 are not limited to the examples described above, and may be one of other interface protocols, such as universal serial bus (USB), multi-media card (MMC), enhanced small disk interface (ESDI), or integrated drive electronics (IDE).

In one or more embodiments, each of the plurality of semiconductor memory devices 32 may be implemented as a dynamic random access memory (DRAM) having dynamic memory cells. In another example, each of the plurality of semiconductor memory devices 32 may be implemented as a phase change random access memory (PRAM), resistive random access memory (RRAM), magnetic random access memory (MRAM), or ferroelectric random access memory (FRAM) having resistive memory cells, but the disclosure is not limited thereto.

The memory controller 34 may control overall operations of the memory system 30 and may control overall data exchange between the host 20 and the plurality of semiconductor memory devices 32. For example, the memory controller 34 may control the plurality of semiconductor memory devices 32 and may program or read data in response to a request of the host 20. Also, the memory controller 34 may control an operation of the plurality of semiconductor memory devices 32 by applying operation commands to control the plurality of semiconductor memory devices 32.

Hereinafter, the memory system may be described in detail with reference to FIG. 2.

FIG. 2 is a block diagram illustrating a memory system according to one or more embodiments.

Referring to FIG. 2, a memory system 100 may include a semiconductor memory device 110 and a memory controller 120. For example, the semiconductor memory device 110 and the memory controller 120 may be connected to each other through a memory interface and may exchange signals through the memory interface.

The storage space of the semiconductor memory device 110 may correspond to a memory cell array 112. The memory cell array 112 may include a plurality of memory banks BANK. Each of the plurality of memory banks BANK may correspond to a storage space in which the semiconductor memory device 110 is divided into bank units. The memory cell array 112 may include 0th to seventh memory banks, but the disclosure is not limited thereto.

Each of the plurality of memory banks BANK may include a plurality of memory cells MC disposed in matrix form. Each of the plurality of memory cells MC may include at least one memory element for storing data. For example, when the semiconductor memory device 110 is implemented as a DRAM, each of the plurality of memory cells MC may include a cell transistor and a cell capacitor performing a switch function.

The memory controller 120 may control an operation of the semiconductor memory device 110 by transmitting signals such as a command CMD and an address ADDR to the semiconductor memory device 110. The command CMD may include an activate command, a read/write command, and/or a refresh command.

For example, the memory controller 120 may transmit an activate command to the semiconductor memory device 110 and may switch a target memory bank of the memory cell array 112 to an activated state. The target memory bank may be one of a plurality of memory banks BANK for writing data DQ to the memory cell array 112 or reading data from the memory cell array 112.

The memory controller 120 may transmit a read command to the semiconductor memory device 110, such that the data DQ may be transferred from the memory cell array 112 to the memory controller 120. The memory controller 12 may transmit a write command to the semiconductor memory device 110, such that the data DQ may be transferred from the memory controller 120 to the memory cell array 112.

According to one or more embodiments, the semiconductor memory device 110 may include a plurality of semiconductor layers including the plurality of memory cells MC. The plurality of semiconductor layers may be stacked in a vertical direction, and the plurality of semiconductor layers may be physically and/or electrically connected to each other in the vertical direction. By increasing the number of stacked semiconductor layers, density of the semiconductor layers may be improved. Accordingly, integration density of the semiconductor memory device 110 may be improved.

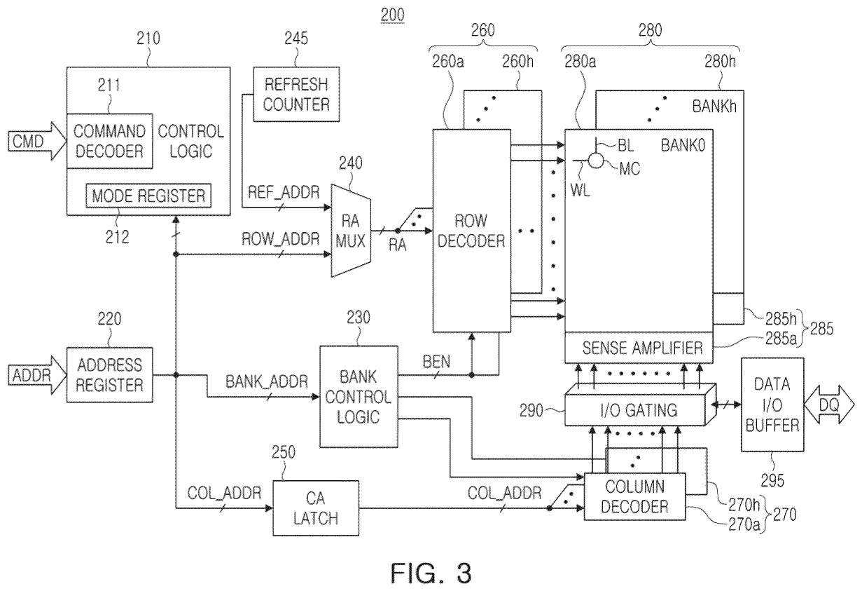

FIG. 3 is a block diagram illustrating the configuration of a semiconductor memory device according to one or more example embodiments.

Referring to FIG. 3, a semiconductor memory device 200 may include a control logic 210, an address register 220, a bank control logic 230, a row address multiplexer 240, a refresh counter 245, a column address latch 250, a row decoder 260, a column decoder 270, a memory cell array 280, a sense amplifier portion 285, an input/output gating circuit 290, and a data input/output buffer 295. When the semiconductor memory device 200 is configured as a resistive semiconductor memory device, the refresh counter 245 may be omitted from the semiconductor memory device 200.

The memory cell array 280 may include a plurality of memory banks 280a-280h. The row decoder 260 may include a plurality of row decoders 260a-260h connected to a plurality of memory banks 280a-280h, respectively. The column decoder 270 may include a plurality of column decoders 270a-270h connected to the plurality of memory banks 280a-280h, respectively. The sense amplifier portion 285 may include a plurality of sense amplifiers 285a-285h connected to the plurality of memory banks 280a-280h, respectively.

Each of the plurality of memory banks 280a-280h may include a plurality of memory cells MC. Each of the plurality of memory cells MC may be disposed at a point at which a plurality of wordlines WL and a plurality of bitlines BL intersect each other. The plurality of memory cells MC may be disposed in a matrix form in the plurality of memory banks 280a-280h. The plurality of memory cells MC may be connected to the row decoder 260 and the sense amplifier portion 285 through the plurality of wordlines WL and the plurality of bitlines BL.

The plurality of memory cells MC may be implemented as a structure such as a planar, a recessed channel array transistor (RCAT), a buried channel array transistor (BCAT), or a vertical channel cell array transistor (VCAT). However, the disclosure is not limited thereto.

The address register 220 may receive an address signal ADDR including a bank address BANK_ADDR, a row address ROW_ADDR, and a column address COL_ADDR from the memory controller (120 in FIG. 2). The address register 220 may provide the received bank address BANK_ADDR to the bank control logic 230, may provide the received row address ROW_ADDR to the row address multiplexer 240, and may provide the received column address COL_ADDR to the column address latch 250.

The bank control logic 230 may generate bank control signals in response to the bank address BANK_ADDR. The bank control signals may include a plurality of bank enable signals BEN for activating only the memory bank corresponding to the bank address BANK_ADDR. A row decoder corresponding to the bank address BANK_ADDR among the plurality of row decoders 260a-260h may be activated in response to the bank control signals. Also, a column decoder corresponding to the bank address BANK_ADDR among the plurality of column decoders 270a-270h may be activated.

The row address multiplexer 240 may receive the row address ROW_ADDR from the address register 220 and the refresh row address REF_ADDR from the refresh counter 245. The row address multiplexer 240 may selectively output the row address ROW_ADDR or the refresh row address REF_ADDR as the row address RA. The row address RA output by the row address multiplexer 240 may be applied to each of the plurality of bank row decoders 260a-260h.

Among the plurality of row decoders 260a-260h, a row decoder activated by the bank control logic 230 may decode the row address RA output by the row address multiplexer 240 and may activate the wordline WL corresponding to the row address RA. For example, an activated row decoder may apply a wordline driving voltage to the wordline WL corresponding to the row address RA.

To distribute the loading applied to the wordline WL, a plurality of wordlines WL may be divided into sub-wordlines to be controlled. The row decoder 260 may include sub-wordline drivers for individually controlling the sub-wordlines. Hereinafter, in example embodiments, the sub-wordlines may be referred to as wordlines. The sub-wordline drivers may correspond to the plurality of wordlines WL and may drive at least one of the plurality of wordlines WL.

The column address latch 250 may receive a column address COL_ADDR from the address register 220 and may temporarily store the received column address COL_ADDR. Also, the column address latch 250 may incrementally increase the received column address COL_ADDR in a burst mode. The column address latch 250 may apply the column address COL_ADDR which may be temporarily stored or incrementally increased to each of the plurality of column decoders 270a-270h.

Among the plurality of column decoders 270a-270h, a column decoder activated by the bank control logic 230 may activate a sense amplifier corresponding to the bank address BANK_ADDR and the column address COL_ADDR through the input/output gating circuit 290.

The input/output gating circuit 290 may include an input data mask logic, read data latches to store data output from a plurality of memory banks 280a-280h, and program drivers for programming data into the plurality of memory banks 280a-280h, along with circuits for gating input/output data.

Data DQ to be read from one of the plurality of memory banks 280a-280h may be sensed by a sense amplifier corresponding to the bank array and may be stored in read data latches. The data DQ stored in the read data latches may be provided to the memory controller (e.g., 120 in FIG. 2) through the data input/output buffer 295.

The data DQ to be programmed to one of the plurality of memory banks 280a-280h may be provided from the memory controller (e.g., 120 in FIG. 2) to the data input/output buffer 295. The data DQ provided to the data input/output buffer 295 may be programmed to the bank array through the program drivers.

The control logic 210 may control an operation of the semiconductor memory device 200. For example, the control logic 210 may generate control signals to allow the semiconductor memory device 200 to perform a program operation or a read operation. The control logic 210 may include a command decoder 211 for decoding a command CMD received from the memory controller (e.g., 120 in FIG. 2) and a mode register set (MR) 212 for setting an operation mode of the semiconductor memory device 200.

For example, the command decoder 211 may decode a program enable signal, a row address strobe signal, a column address strobe signal, and a chip select signal to generate operation control signals corresponding to the command CMD.

The semiconductor memory device 200 may have a cell on periphery (CoP) structure or a periphery on cell (PoC) structure in which the plurality of semiconductor layers are stacked in the vertical direction. The plurality of semiconductor layers may be physically and/or electrically connected to each other.

According to one or more embodiments, one of the plurality of semiconductor layers may include sub-wordline drivers and a plurality of sense amplifiers 285a-285h, other than the plurality of memory banks 280a-280h. The plurality of memory banks 280a-280h may be otherwise isolated from each other in the other layers of the plurality of semiconductor layers.

According to an example embodiment, by increasing the number of semiconductor layers in which the plurality of memory banks 280a-280h are isolated from each other, and connecting the layers to each other in the vertical direction, density of the semiconductor layers may be improved. Accordingly, integration density of the semiconductor memory device 200 may be improved.

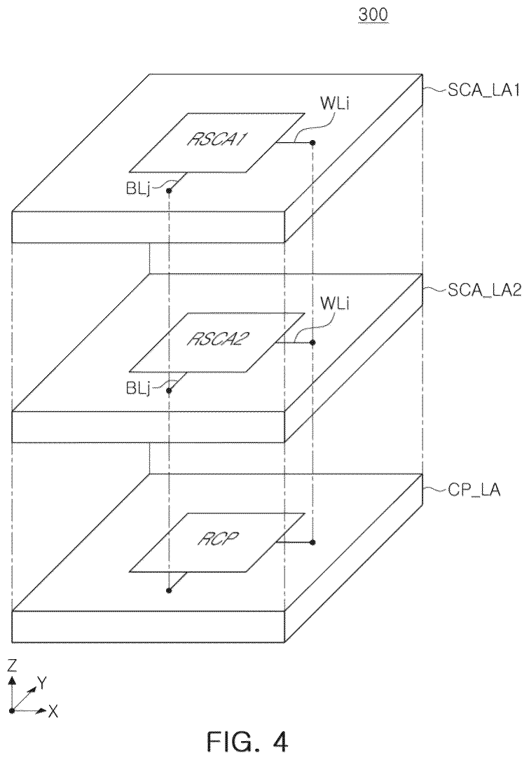

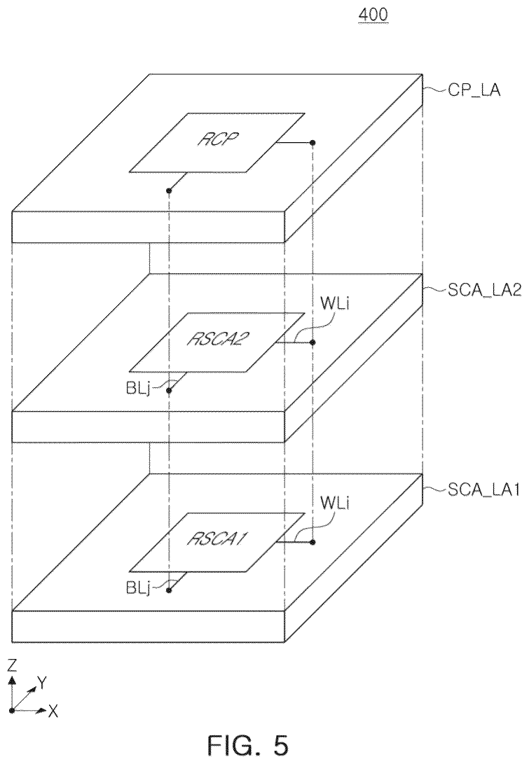

Hereinafter, the plurality of semiconductor layers of the semiconductor memory device 200 may be described in detail with reference to FIGS. 4 and 5.

FIGS. 4 and 5 are diagrams illustrating a plurality of semiconductor layers of a semiconductor memory device according to example embodiments.

The semiconductor memory device 300 and 400 may include a row decoder, a column decoder, a memory cell array including a plurality of sub-cell arrays, a sense amplifier, and a data input/output buffer. The row decoder may include sub-wordline drivers for individually controlling sub-wordlines. Specific example embodiments of the semiconductor memory device may be similar to the example described with reference to FIGS. 1 to 3.

Referring to FIGS. 4 and 5, the semiconductor memory device 300 and 400 may include a plurality of semiconductor layers. For example, the semiconductor memory device 300 and 400 may include a core peripheral semiconductor layer CP_LA and first and second sub-cell array semiconductor layers SCA_LA1 and SCA_LA2.

The first sub-cell array semiconductor layer SCA_LA1 may include a first sub-cell array region RSCA1 including a plurality of sub-cell arrays. The second sub-cell array semiconductor layer SCA_LA2 may include a second sub-cell array region RSCA2 including a plurality of sub-cell arrays.

The sub-cell array may include a plurality of memory cells disposed in matrix form. Each of the plurality of memory cells may be disposed at a point at which a plurality of wordlines WL and a plurality of bitlines BL intersect each other. The first and second sub-cell array regions RSCA1 and RSCA2 may include the same number of memory cells, but the disclosure is not limited thereto.

The core peripheral semiconductor layer CP_LA may include components such as a row decoder and a column decoder in addition to the sub-cell array SCA. According to an example embodiment, the core peripheral semiconductor layer CP_LA may include a core peripheral region RCP. The core peripheral region RCP may include a plurality of sub-wordline drivers and a plurality of sense amplifiers. The memory cell may be connected to the sub-wordline driver through the wordline WL and to the sense amplifier through the bitline BL.

The plurality of semiconductor layers SCA_LA1, SCA_LA2, and CP_LA may be stacked in the first direction (Z-axis direction in FIGS. 4 and 5). Referring to FIG. 4, the first and second sub-cell array semiconductor layers SCA_LA1 and SCA_LA2 may be stacked on the core peripheral semiconductor layer CP_LA, such that the semiconductor memory device 300 may have a CoP structure. Referring to FIG. 5, the core peripheral semiconductor layer CP_LA may be stacked on the first and second sub-cell array semiconductor layers SCA_LA1 and SCA_LA2, such that the semiconductor memory device 400 may have a PoC structure.

The core peripheral region RCP may partially overlap at least one of the first and second sub-cell array regions RSCA1 and RSCA2 in the first direction. In the example embodiment illustrated in FIGS. 4 and 5, the core peripheral region RCP and the first and second sub-cell array regions RSCA1 and RSCA2 may overlap each other in the first direction. However, the disclosure is not limited thereto.

In the plurality of semiconductor layers SCA_LA1, SCA_LA2, and CP_LA, the plurality of wordlines WL may extend in the second direction (the X-axis direction in FIGS. 4 and 5). The plurality of bitlines BL may extend in the third direction (the Y-axis direction in FIGS. 4 and 5). In the plurality of semiconductor layers SCA_LA1, SCA_LA2, and CP_LA, the plurality of wordlines WL may overlap each other in the first direction, and the plurality of bitlines BL may overlap each other in the first direction. However, the disclosure is not limited thereto.

According to an example embodiment, the plurality of wordlines WL included in the first sub-cell array semiconductor layer SCA_LA1 may be respectively connected to the plurality of wordlines WL included in the second sub-cell array semiconductor layer SCA_LA2 in the first direction. The plurality of wordlines WL connected to each other in the first direction may be connected to the core peripheral region RCP, and specifically, each of the plurality of wordlines WL connected to each other in the first direction may be connected to one of the plurality of sub-wordline drivers.

According to an example embodiment, the plurality of bitlines BL included in the first sub-cell array semiconductor layer SCA_LA1 may be respectively connected to the plurality of bitlines BL included in the second sub-cell array semiconductor layer SCA_LA2 in the first direction. The plurality of bitlines BL connected to each other in the first direction may be connected to the core peripheral region RCP, and specifically, each of the plurality of wordlines WL connected to each other in the first direction may be connected to one of the plurality of sense amplifiers.

For example, the ith wordline WLi may extend in the second direction from each of the first and second sub-cell array semiconductor layers SCA_LA1 and SCA_LA2. The extended ith wordline WLi may be physically and/or electrically connected to each other in the first direction, and may be connected to the core peripheral region RCP.

The jth bitline BLj may extend in the third direction from each of the first and second sub-cell array semiconductor layers SCA_LA1 and SCA_LA2. The extended jth bitline BLj may be physically and/or electrically connected to each other in the first direction, and may be connected to the core peripheral region RCP.

In a general semiconductor memory device including a plurality of sub-cell array semiconductor layers, a core peripheral semiconductor layer and a plurality of sub-cell array semiconductor layers are not connected to each other, and each of the plurality of sub-cell array semiconductor layers may be connected to the core peripheral semiconductor layer.

In other words, a single sub-wordline driver may be connected to a wordline included in one of a plurality of sub-cell array semiconductor layers, and may not be connected to wordlines included in the other sub-cell array semiconductor layers. A sense amplifier may be connected to a bitline included in one of the plurality of sub-cell array semiconductor layers, and may not be connected to bitlines included in the other sub-cell array semiconductor layers.

Differently from the above example, in the semiconductor memory device 300 and 400 in an example embodiment, the core peripheral semiconductor layer CP_LA and the plurality of sub-cell array semiconductor layers SCA_LA may be physically and/or electrically connected to each other. Specifically, each of the wordlines WL included in the plurality of sub-cell array semiconductor layers SCA_LA may be connected to each other in the first direction, and each of the bitlines BL included in the plurality of sub-cell array semiconductor layers SCA_LA may also be connected to each other in the first direction.

In other words, the sub-wordline driver may be connected to a wordline WL connected in the first direction among wordlines included in the plurality of sub-cell array semiconductor layers. A sense amplifier may be connected to a bitline BL connected in the first direction among bitlines included in the plurality of sub-cell array semiconductor layers.

Accordingly, the size of the core peripheral semiconductor layer CP_LA may be maintained the same, and the number of sub-cell array semiconductor layers SCA_LA coupled to the core peripheral semiconductor layer CP_LA may be increased. In other words, the number of sub-wordline drivers and the number of sense amplifiers may be maintained the same, and the number of memory cells connected to the sub-wordline driver and the sense amplifier may be increased.

Alternatively, the number of sub-cell array semiconductor layers SCA_LA coupled to the core peripheral semiconductor layer CP_LA may be maintained the same, and the size of the core peripheral semiconductor layer CP_LA may be reduced. In other words, the number of sub-wordline drivers and the number of sense amplifiers may be reduced, and memory cells connected to the sub-wordline drivers and the sense amplifiers may be isolated from each other by the plurality of sub-cell array semiconductor layers.

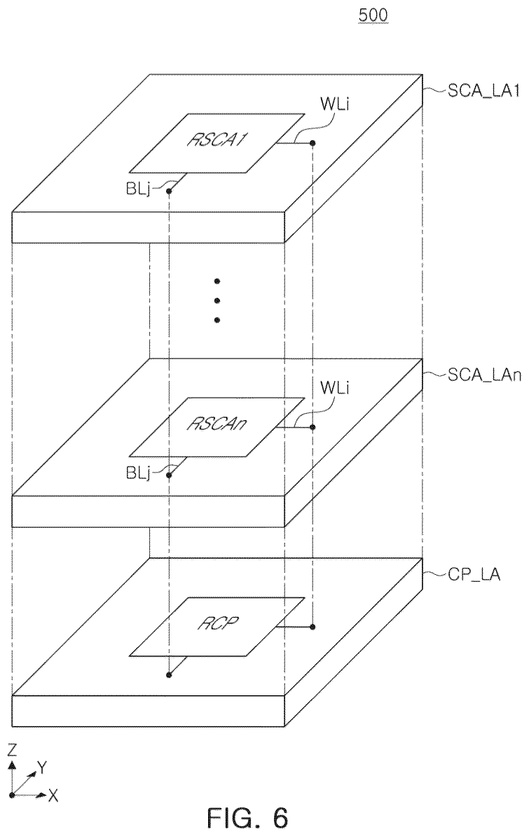

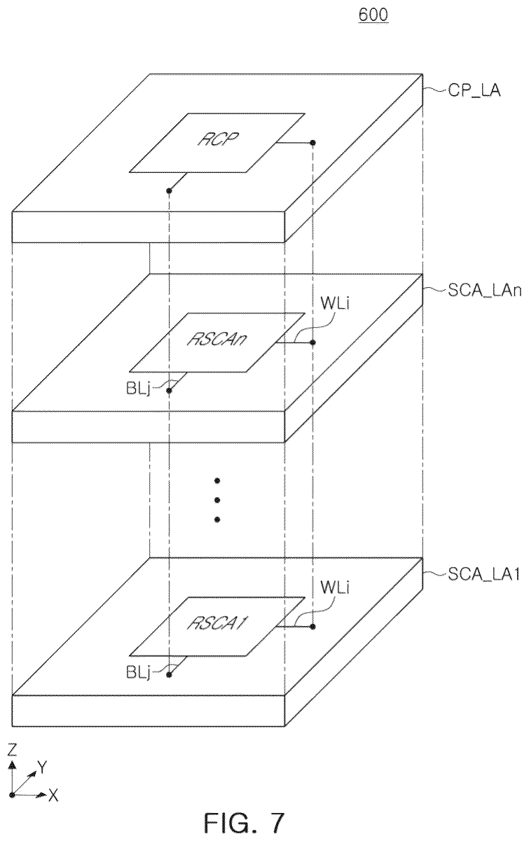

FIGS. 6 and 7 are diagrams illustrating the plurality of semiconductor layers of a semiconductor memory device according to example embodiments.

The semiconductor memory device 500 and 600 may include a row decoder, a column decoder, a memory cell array including a plurality of sub-cell arrays, a sense amplifier, and a data input/output buffer. The row decoder may include sub-wordline drivers for individually controlling the sub-wordlines. Specific example embodiments of the semiconductor memory device may be similar to the example described with reference to FIGS. 1 to 3.

Referring to FIGS. 6 and 7, the semiconductor memory device 500 and 600 may include a plurality of semiconductor layers. For example, the semiconductor memory device 500 and 600 may include a core peripheral semiconductor layer CP_LA and first to nth sub-cell array semiconductor layers SCA_LA1-SCA_LAn.

Each of the first to nth sub-cell array semiconductor layers SCA_LA1-SCA_LAn may include first to nth sub-cell array regions RSCA1-RSCAn including a plurality of sub-cell arrays. The sub-cell array may include a plurality of memory cells disposed in matrix form. Each of the plurality of memory cells may be disposed at a point at which a plurality of wordlines WL and a plurality of bitlines BL intersect each other.

The core peripheral semiconductor layer CP_LA may include the other components such as a row decoder and a column decoder in addition to the sub-cell array SCA. According to an example embodiment, the core peripheral semiconductor layer CP_LA may include a core peripheral region RCP. The core peripheral region RCP may include a plurality of sub-wordline drivers and a plurality of sense amplifiers. The memory cell may be connected to a sub-wordline driver through a wordline WL and to a sense amplifier through a bitline BL.

A plurality of semiconductor layers SCA_LA1-SCA_Lan and CP_LA may be stacked in the first direction (Z-axis direction in FIGS. 6 and 7).

Referring to FIG. 6, the first to nth sub-cell array semiconductor layers SCA_LA1-SCA_LAn are stacked on the core peripheral semiconductor layer CP_LA, such that the semiconductor memory device 500 may have a CoP structure. Compared to the semiconductor memory device 300 in FIG. 4, the number of sub-cell array semiconductor layers may be different.

Referring to FIG. 7, the core peripheral semiconductor layer CP_LA may be stacked on the first to nth sub-cell array semiconductor layers SCA_LA1-SCA_LAn, such that the semiconductor memory device 600 may have a PoC structure. Compared to the semiconductor memory device 400 in FIG. 5, the number of sub-cell array semiconductor layers may be different.

In the semiconductor memory devices 500 and 600 in FIGS. 6 and 7, specific example embodiments other than the number of sub-cell array semiconductor layers stacked in the first direction may be similar to the example described in FIGS. 4 and 5 above. Compared to FIGS. 4 and 5, the semiconductor memory devices 500 and 600 may have more sub-cell array semiconductor layers SCA_LA stacked, thereby further improving integration density.

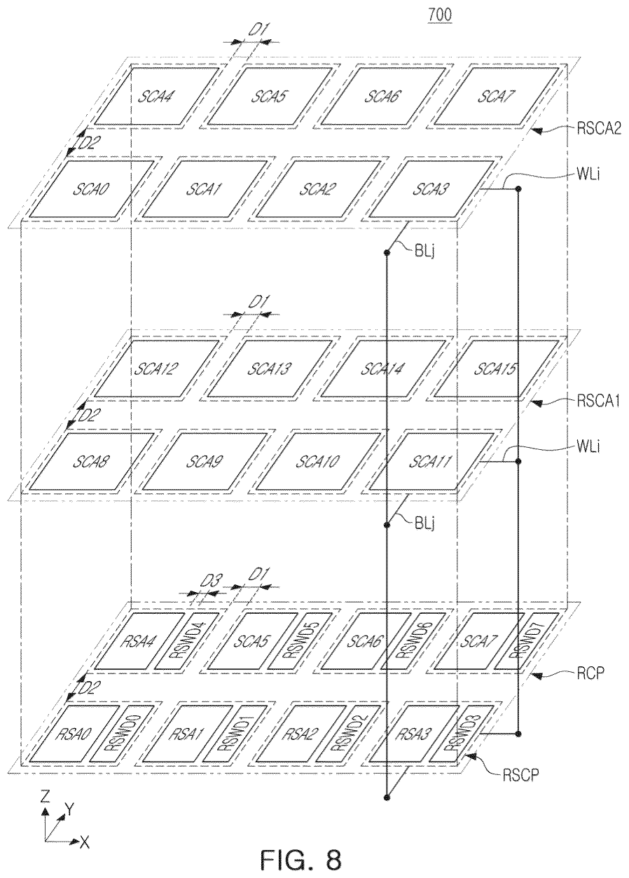

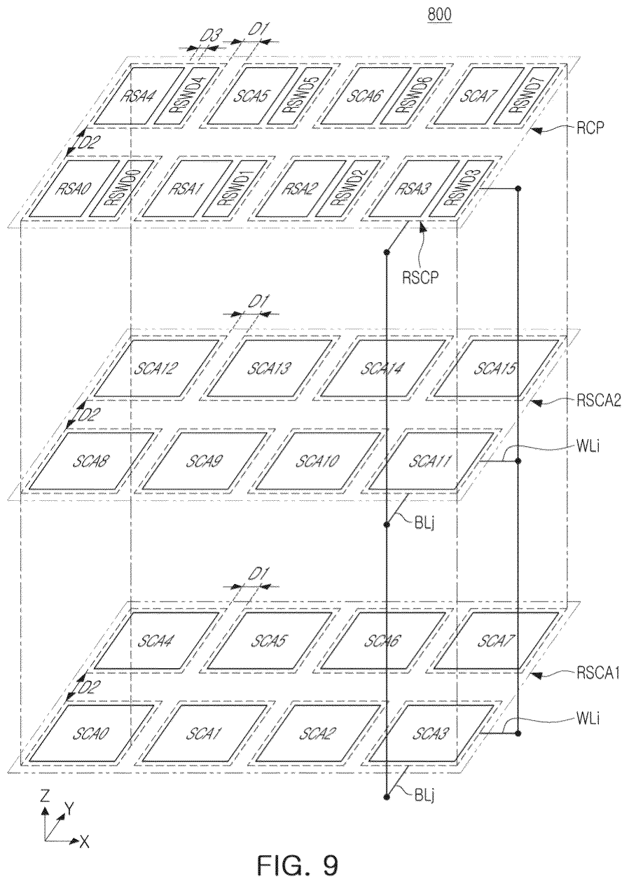

Hereinafter, a layout of the semiconductor memory device may be described in detail with reference to FIGS. 8 and 9.

FIGS. 8 and 9 are diagrams illustrating a layout of a semiconductor memory device according to example embodiments.

Referring to FIGS. 6 and 7, semiconductor memory devices 700 and 800 may include a plurality of semiconductor layers stacked in a first direction (Z-axis direction in FIGS. 8 and 9). The semiconductor memory devices 700 and 800 may include a first sub-cell array semiconductor layer including a first sub-cell array region RSCA1, a second sub-cell array semiconductor layer including a second sub-cell array region RSCA2, and a core peripheral semiconductor layer including a core peripheral region RCP. Specific example embodiments of the semiconductor memory devices 700 and 800 may be similar to the example described with reference to FIGS. 1 to 7.

According to an example embodiment illustrated in FIG. 6, the first sub-cell array region RSCA1 and the second sub-cell array region RSCA2 may be stacked on the core peripheral region RCP. The semiconductor memory device 700 may have a CoP structure similar to the semiconductor memory device 300 in the example embodiment illustrated in FIG. 4.

According to an example embodiment illustrated in FIG. 7, a core peripheral region RCP may be stacked on the first sub-cell array region RSCA1 and the second sub-cell array region RSCA2. The semiconductor memory device 800 may have a PoC structure similar to the semiconductor memory device 400 in the example embodiment illustrated in FIG. 5.

The first sub-cell array region RSCA1 may include a plurality of first sub-cell array SCAs, and the second sub-cell array region RSCA2 may include a plurality of second sub-cell array SCAs. The number of first sub-cell array SCAs included in the first sub-cell array region RSCA1 may be the same as or different from the number of sub-cell array SCAs included in the second sub-cell array region RSCA2.

Referring to FIG. 6 and FIG. 7, the first sub-cell array region RSCA1 may include 0th to seventh sub-cell arrays SCA0-SCA7, and each of the 0th to seventh sub-cell arrays SCA0-SCA7 may correspond to the first sub-cell array. The second sub-cell array region RSCA2 may include eighth to fifteenth sub-cell arrays SCA8-SCA15, and each of the eighth to fifteenth sub-cell arrays SCA8-SCA15 may correspond to the second sub-cell array. As an example embodiment illustrated in FIG. 6, each of the first and second sub-cell array regions RSCA1 and RSCA2 may include eight sub-cell arrays.

The 0th to fifteenth sub-cell arrays SCA0-SCA15 may have the same size. However, the disclosure is not limited thereto, and at least one sub-cell array SCA may have a different size.

The 0th to seventh sub-cell array SCA0-SCA7 may be disposed identically or differently from the eighth to fifteenth sub-cell array SCA8-SCA15. As an example embodiment illustrated in FIG. 6, the 0th to seventh sub-cell array SCA0-SCA7 may be disposed in matrix form, and the eighth to fifteenth sub-cell arrays SCA8-SCA15 may be disposed similarly.

In the first sub-cell array region RSCA1, the 0th to third sub-cell arrays SCA0-SCA3 and the fourth to seventh sub-cell arrays SCA4-SCA7 may be disposed linearly in the second direction (the X-axis direction in FIGS. 8 and 9). Each of a pair of sub-cell arrays SCA, such as the 0th sub-cell array SCA0 and the fourth sub-cell array SCA4, may be disposed linearly in the third direction (the Y-axis direction in FIGS. 8 and 9).

In the second sub-cell array region RSCA2, the eighth to first1 sub-cell arrays SCA8-SCA11 and the twelfth to fifteenth sub-cell arrays SCA12-SCA15 may be disposed linearly in the second direction. Each of a pair of sub-cell arrays SCA, such as the eighth sub-cell array SCA8 and the twelfth sub-cell array SCA12, may be disposed linearly in the third direction.

A distance D1 between the plurality of sub-cell arrays SCA in the second direction may be less than a distance D2 between the plurality of sub-cell arrays SCA in the third direction. However, the disclosure is not limited thereto.

The core peripheral region RCP may include a plurality of sub-core peripheral regions RSCP. The sub-core peripheral region RSCP may include a sub-wordline driver region RSWD and a sense amplifier region RSA.

The sub-wordline driver region RSWD may include a plurality of sub-wordline drivers. A plurality of wordlines WL may be connected to the sub-wordline driver region RSWD. The plurality of sense amplifier regions RSA may include a plurality of sense amplifiers. A plurality of bitlines BL may be connected to the plurality of sense amplifier regions RSA.

The sizes of the entirety of sub-wordline driver regions RSWD may be the same. The sizes of the sense amplifier regions RSA may be the same. Accordingly, the sizes of the sub-core peripheral regions RSCP may be the same. The size of the sub-wordline driver region RSWD may be greater than the size of the sense amplifier region RSA, but the disclosure is not limited thereto, and the size of the sub-wordline driver region RSWD may be the same as or smaller than the size of the sense amplifier region RSA.

As the example embodiment illustrated in FIG. 8 and FIG. 9, the plurality of sub-core peripheral regions RSCP may also be disposed in matrix form. The arrangement of the plurality of sub-core peripheral regions RSCP, the arrangement of the plurality of first sub-cell arrays SCA0-SCA7, and the arrangement of the plurality of second sub-cell arrays SCA8-SCA15 may be the same.

In the sub-core peripheral region RSCP, the sub-wordline driver region RSWD and the sense amplifier region RSA may be disposed in the first direction. A plurality of sub-wordline driver regions RSWD may be disposed in the first direction between the plurality of sense amplifier regions RSA. A plurality of sense amplifier regions RSA and a plurality of sub-wordline driver regions RSWD may be disposed adjacent to each other in the second direction. Accordingly, the plurality of sub-wordline driver regions RSWD and the plurality of sense amplifier regions RSA may also be disposed in matrix form.

A distance D1 in the second direction between the plurality of sub-core peripheral regions RSCP may be less than a distance D2 in the third direction between a plurality of sub-core peripheral regions RSCP. The distances D1 and D2 between the plurality of sub-core peripheral regions RSCP may be the same as the distances D1 and D2 between the plurality of sub-cell arrays SCA in the second and third directions.

The distance D3 in the second direction between the sub-wordline driver region RSWD and the plurality of sense amplifier regions RSA included in the sub-core peripheral region RSCP may be less than the distance D1 between the plurality of sub-core peripheral regions RSCP.

The sub-core peripheral region RSCP may further include a conjunction region. The conjunction region may include a plurality of wordline driving signal generator circuits. The plurality of wordline driving signal generator circuits may supply a high voltage higher than a power supply voltage to selected wordlines and may apply a low voltage lower than a ground voltage to unselected wordlines. The conjunction region may be disposed between the sense amplifier region RSA and the sub-wordline driver region RSWD in the first direction.

Referring to FIGS. 8 and 9, the core peripheral region RCP, the first sub-cell array region RSCA1, and the second sub-cell array region RSCA2 may overlap each other in the first direction. Specifically, the sub-core peripheral region RSCP may overlap the sub-cell array SCA of each of the first and second sub-cell array regions RSCA1 and RSCA2 in the first direction. For example, the third sub-cell array SCA3 and the first1 sub-cell array SCA11 may overlap the sub-core peripheral region RSCP including the third sub-wordline driver RSWD3 and the third sense amplifier region RSA3 in the first direction.

Each of the first sub-cell array region RSCA1 and the second sub-cell array region RSCA2 may include a plurality of wordlines WL and a plurality of bitlines BL. Specifically, each of the plurality of sub-cell arrays SCA may include a plurality of wordlines WL and a plurality of bitlines BL.

The plurality of wordlines WL may extend in the second direction. The plurality of bitlines BL may extend in the third direction. The plurality of wordlines WL included in the first sub-cell array region RSCA1 may overlap the plurality of wordlines WL included in the second sub-cell array region RSCA2 in the first direction. The plurality of bitlines BL included in the first sub-cell array region RSCA1 may overlap the plurality of bitlines BL included in the second sub-cell array region RSCA2 in the first direction.

According to an example embodiment, the plurality of wordlines WL included in the first sub-cell array may be connected to the plurality of wordlines WL included in the second sub-cell array in the first direction, respectively. The plurality of wordlines WL connected to each other in the first direction may be connected to the sub-wordline driver region RSWD. Specifically, each of the plurality of wordlines WL connected to each other in the first direction may be connected to one of the plurality of sub-wordline drivers.

According to an example embodiment, the plurality of bitlines BL included in the first sub-cell array may be connected to the plurality of bitlines BL included in the second sub-cell array in the first direction, respectively. The plurality of bitlines BL connected to each other in the first direction may be connected to the sense amplifier region RSA. Specifically, each of the plurality of bitlines BL connected to each other in the first direction may be connected to one of the plurality of sense amplifiers.

As an example, the ith wordline WLi may extend in the second direction in each of the third and first1 sub-cell arrays SCA3 and SCA11. The extended ith wordline WLi may be physically and/or electrically connected to each other in the first direction and may be connected to the third sub-wordline driver region RSWD3. Specifically, the ith wordline WLi may be connected to one of the plurality of sub-wordline drivers included in the third sub-wordline driver region RSWD3.

The jth bitline WLj may extend in the third direction in each of the third and first1 sub-cell arrays SCA3 and SCA11. The extended jth bitline WLj may be physically and/or electrically connected to each other in the first direction and may be connected to the third sense amplifier region RSA3. Specifically, the jth bitline WLj may be connected to one of the plurality of sense amplifiers included in the third sense amplifier region RSA3.

The semiconductor memory devices 700 and 800 according to an example embodiment may include a plurality of sub-cell array regions RSCA stacked in the first direction. Wordlines WL overlapping each other in the first direction may be connected to each other in the first direction, and bitlines BL overlapping each other in the first direction may be connected to each other in the first direction and may be connected to the core peripheral region RCP. Accordingly, the number of sub-cell array regions RSCA connected to a core peripheral region RCP may be increased, thereby improving integration density of the semiconductor memory device 500.

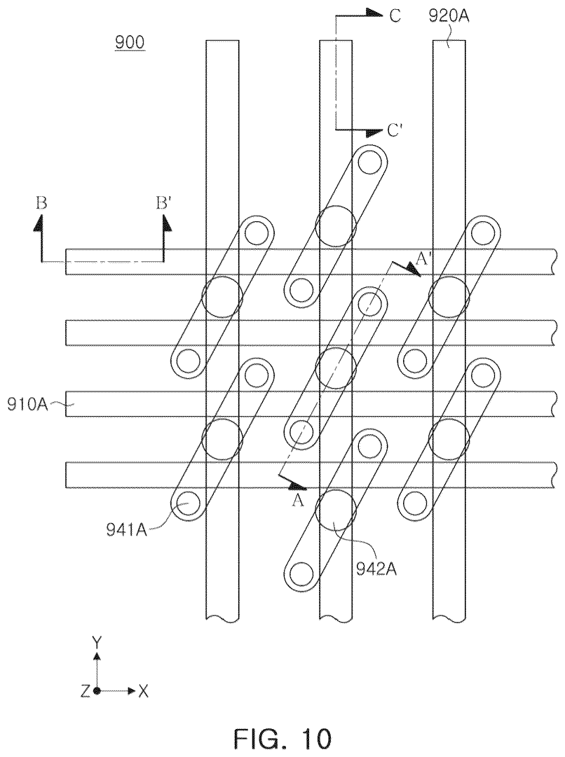

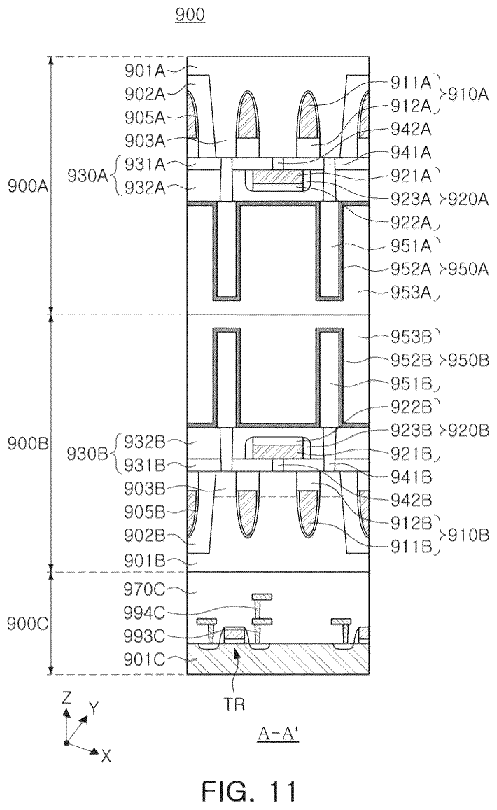

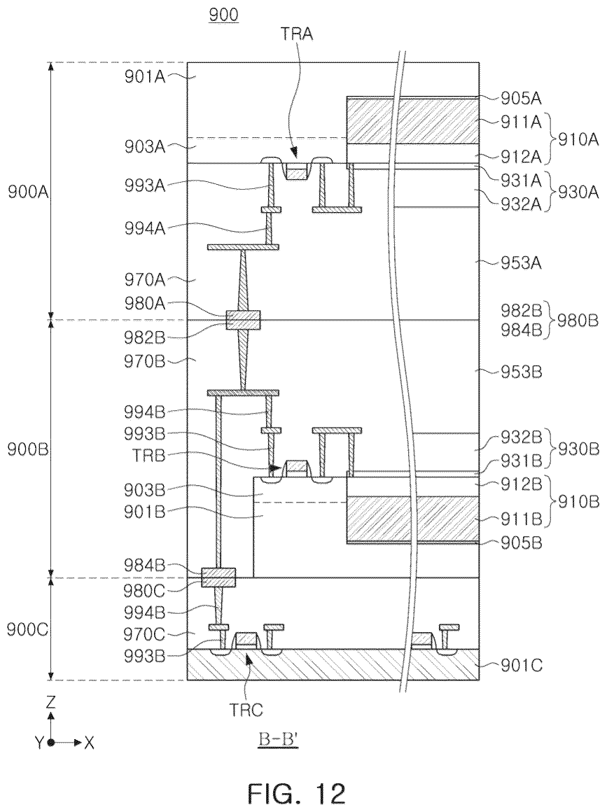

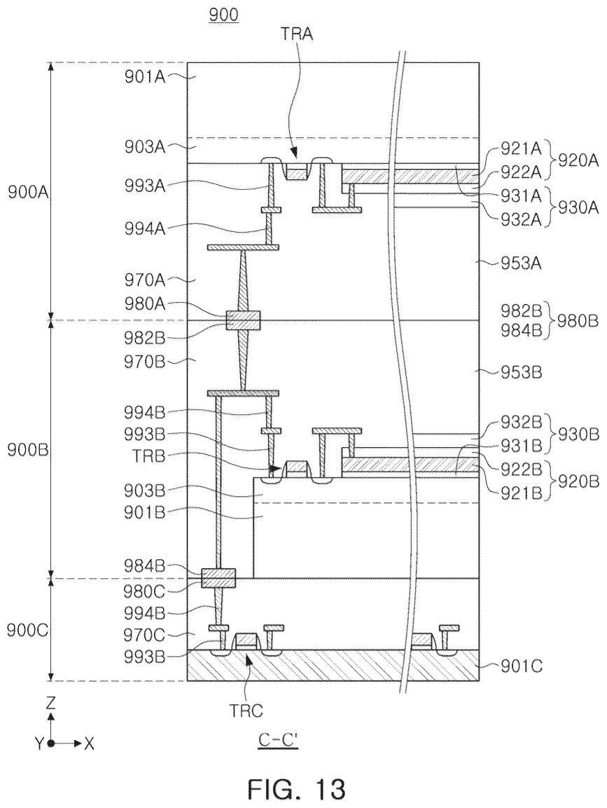

FIG. 10 is a plan diagram illustrating a semiconductor memory device according to an example embodiment. FIG. 11 is a cross-sectional diagram illustrating a cross-sectional surface of the semiconductor memory device illustrated in FIG. 10 in A-A′ direction. FIG. 12 is a cross-sectional diagram illustrating a cross-sectional surface of the semiconductor memory device illustrated in FIG. 10 in B-B′ direction. FIG. 13 is a cross-sectional diagram illustrating a cross-sectional surface of the semiconductor memory device illustrated in FIG. 10 in C-C′ direction.

In an example embodiment illustrated in FIGS. 10 to 13, a semiconductor memory device 900 according to an example embodiment may include a region A 900A, a region B 900B, and a region C 900C.

The region 900A may correspond to a first sub-cell array semiconductor layer in which a plurality of memory cells are formed, the region A 900A may correspond to a first sub-cell array semiconductor layer in which a plurality of memory cells are formed, the region B 900B may correspond to a second sub-cell array semiconductor layer in which a plurality of memory cells are formed, and the region C 900C may correspond to a core peripheral semiconductor layer in which a plurality of sub-wordline drivers and a plurality of sense amplifiers, other than a plurality of memory cells, are formed.

In the region 900A and the region B 900B, the active regions 903A and 903B defined between element isolation films 902A and 902B, gate structures 910A and 910B providing wordlines, bitline structures 920A and 920B connected to at least a portion of the active regions 903A and 903B, and capacitor structures 950A and 950B can be formed. The gate structures 910A and 910B may intersect the active regions 903A and 903B and the bitline structures 920A and 920B, and may be embedded in the substrates 901A and 901B.

The gate structures 910A and 910B may include gate electrode layers 911A and 911B and capping layers 912A and 912B. The gate electrode layers 911A and 911B may be formed of a conductive material such as a metal or a metal compound, and the capping layers 912A and 912B may be formed of an insulating material such as silicon nitride. The gate insulating layers 905A and 905B may be disposed between the gate electrode layers 911A and 911B and the substrates 901A and 901B, and the gate insulating layers 905A and 905B may be formed of silicon oxide.

The active regions 903A and 903B may be doped with impurities and may provide a source region and a drain region of a cell switch included in a memory cell. The active regions 903A and 903B disposed between the gate structures 910A and 910B and the element isolation films 902A and 902B may be connected to the capacitor structures 950A and 950B through the first contacts 941A and 941B. The active regions 903A and 903B disposed between a pair of adjacent gate structures 910A and 910B may be connected to the bitline structures 920A and 920B through the second contacts 942A and 942B.

The bitline structures 920A and 920B may be embedded in the intermediate insulating layers 930A and 930B together with the first contacts 941A and 941B and the second contacts 942A and 942B. The intermediate insulating layers 930A and 930B may include first intermediate insulating layers 931A and 931B and second intermediate insulating layers 932A and 932B. The bitline structures 920A and 920B may include bitline conductive layers 921A and 921B, bitline capping layers 922A and 922B and spacer layers 923A and 923B.

The capacitor structures 950A and 950B may be connected to the active regions 903A and 903B through the first contacts 941A and 941B and may include lower electrode layers 951A, 951B, dielectric layers 952A and 952B and upper electrode layers 953A and 953B. The capacitor structures 950A and 950B may extend in the first direction (Z-axis direction in FIGS. 10 to 13) perpendicular to the upper surface of the substrates 901A and 901B.

In the region C 900C, a substrate 901C, a plurality of semiconductor elements TR formed on the substrate 901C, a C insulating layer 970C, a plurality of interconnection patterns 993C and 994C formed on the C insulating layer 970C and connected to a plurality of semiconductor elements TR may be formed. The plurality of interconnection patterns 993C and 994C may include an element contact 993C and a lower interconnection 994C.

Referring to FIGS. 12 and 13, the region A 900A, the region b 900B, and the region C 900C may further include bonding pads 980A, 980B, and 980C. The bonding pads 980A, 980B, and 980C may be formed of copper (Cu), but the disclosure is not limited thereto. The bonding pads 980A, 980B, and 980C may be formed on an upper surface and/or a lower surface of the region A 900A to the region C 900C.

Referring to FIGS. 11 to 13, the region A 900A, the region B 900B, and the region C 900C may be stacked in the first direction. The region A 900A and the region B 900B may be stacked on the region C 900C, and the region A 900A may be stacked on the region B 900B. Accordingly, a plan diagram illustrating a semiconductor memory device 900 according to an example embodiment, illustrated in FIG. 10, may correspond to a plane of the region A 900A.

The semiconductor memory device 900 may have a CoP structure, and specific example embodiments of the semiconductor memory device having a CoP structure may be similar to the example described with reference to FIG. 4. However, the disclosure is not limited thereto.

A region A 900A, a region B 900B, and a region C 900C may be directly bonded and coupled (hybrid bonding) or directly bonded between one surface of the region and one surface of the other region without a connecting member such as a metal bump. However, the method of bonding the regions 900A, 900B and 900C is not limited thereto.

The upper surface and the lower surface of the regions A 900A, B 900B, and C 900C may oppose each other. By predetermined processes such as a heat treatment, the surfaces of the bonding pads 980A, 980B, and 980C opposing each other may be coupled to each other, and the surfaces of the insulating layers 970A, 970B, and 970C opposing each other may be coupled to each other. Accordingly, the regions A 900A, B 900B and C 900C may be coupled to each other.

The bonding pad 980A may be formed on the upper surface of the region A 900A. The B bonding pad 980B may include a B upper-surface bonding pad 982B formed on the upper surface of the region B 900B and a B lower-surface bonding pad 984B formed on the lower surface of the region B 900B. The C bonding pad 980C may be formed on the upper surface of the region C 900C. Specifically, the A through C bonding pads 980A, 980B, and 980C may be formed on the upper surface and/or the lower surface of insulating layers 970A, 970B, and 970C of each region.

For example, the region A 900A may be stacked with the region B 900B in a flipped state. The A bonding pad 980A formed on the upper surface of the region A 900A may oppose and be coupled to the B upper-surface bonding pad 982B formed on the upper surface of the region B 900B. The upper surface of the A insulating layer 970A may oppose and be coupled to the upper surface of the B insulating layer 970B.

The region B 900B and the region C 900C may be stacked. The B lower-surface bonding pad 984B formed on the lower surface of the region B 900B may oppose and be coupled to the C bonding pad 980C formed on the upper surface of the region C 900C. A portion of the lower surface of the region C 900C may oppose and be coupled to the lower surface of the region B 900B, other than the B lower-surface bonding pad 984B and the B substrate 901B.

Referring to FIG. 12 and FIG. 13, a plurality of A interconnection patterns 993A and 994A and at least one A semiconductor element TRA may be further formed in the region A 900A, and a plurality of B interconnection patterns 993B and 994B and at least one B semiconductor element TRB may be further formed in the region B 900B.

In an example embodiment illustrated in FIG. 12, the A gate structure 910A formed in the region A 900A and the B gate structure 910B formed in the region B 900B may extend in the second direction (the X-axis direction in FIG. 10 to FIG. 13). The A and B gate structures 910A and 910B may overlap each other in the first direction, but the disclosure is not limited thereto.

The plurality of A interconnection patterns 993A and 994A may connect the A gate structure 910A to the A semiconductor element TRA, and may connect the A semiconductor element TRA to the A bonding pad 980A. The plurality of B interconnection patterns 993B and 994B may connect the B gate structure 910B to the B semiconductor element TRB. Also, the plurality of B interconnection patterns 993B and 994B may connect the B semiconductor element TRB to the B upper-surface bonding pad 982B and the B lower-surface bonding pad 984B.

That is, since the A bonding pad 980A and the B upper-surface bonding pad 982B are coupled each other, the A gate structure 910A may be connected to the B gate structure 910B in the first direction.

The plurality of C interconnection patterns 993C and 994C may be connected to the C semiconductor element TRC and the C bonding pad 980C. Since the B lower-surface bonding pad 984B and the C bonding pad 980C formed on the upper surface of region C 900C are coupled to each other, the A and B gate structures 910A and 910B connected to each other in the first direction may be connected to the C semiconductor element TRC. The C semiconductor element TRC may correspond to a portion included in the sub-wordline driver. In other words, the A and B gate structures 910A and 910B connected to each other in the first direction may be connected to the sub-wordline driver.

In an example embodiment, each of the A semiconductor element TRA and the B semiconductor element TRB may be configured as a switch element. In another example embodiment, the A semiconductor element TRA and the B semiconductor element TRB may correspond to a portion included in a demultiplexer circuit. Signals transferred from the sub-wordline driver may be transferred to one of the A gate structure 910A and the B gate structure 910B by the A and B semiconductor elements TRA and TRB.

Differently from the example embodiment illustrated in FIG. 12, the region A 900A and the region B 900B may not include the A and B semiconductor elements TRA and TRB. The A and B gate structures 910A and 910B may be connected to each other in the first direction without being connected to the A and B semiconductor elements TRA and TRB. Signals transferred from the sub-wordline driver may be transferred to the A gate structure 910A and the B gate structure 910B.

As an example embodiment illustrated in FIG. 13, the A bitline structure 920A formed in the region A 900A and the B bitline structure 920B formed in the region B 900B may extend in the third direction (the Y-axis direction in FIGS. 10 to 13). The A and B bitline structures 920A and 920B may overlap each other in the first direction, but the disclosure is not limited thereto.

The plurality of A interconnection patterns 993A and 994A may connect the A bitline structure 920A to the A semiconductor element TRA, and may connect the A semiconductor element TRA to the A bonding pad 980A. The plurality of B interconnection patterns 993B and 994B may connect the B bitline structure 920B to the B semiconductor element TRB. Also, the plurality of B interconnection patterns 993B and 994B may connect the B semiconductor element TRB to the B upper-surface bonding pad 982B and the B lower-surface bonding pad 984B.

That is, since the A bonding pad 980A and the B upper-surface bonding pad 982B are coupled to each other, the A bitline structure 920A may be connected to the B bitline structure 920B in the first direction.

The plurality of C interconnection patterns 993C and 994C may connect the C semiconductor element TRC to the C bonding pad 980C. Since the B lower-surface bonding pad 984B and the C bonding pad 980C formed on the upper surface of the region C 900C are coupled to each other, the A and B bitline structures 920A and 920B connected to each other in the first direction may be connected to the C semiconductor element TRC. The C semiconductor element TRC may correspond to a portion included in the sense amplifier. In other words, the A and B bitline structures 920A and 920B connected to each other in the first direction may be connected to the sense amplifier.

In an example embodiment, each of the A semiconductor element TRA and the B semiconductor element TRB may be configured as a switch element. In another example embodiment, the A semiconductor element TRA and the B semiconductor element TRB may correspond to a portion included in a demultiplexer circuit. Signals transferred from the sense amplifier may be transferred to one of the A bitline structure 920A and the B bitline structure 920B by the A and B semiconductor elements TRA and TRB.

Alternatively, the region A 900A and the region B 900B may not include the A and B semiconductor elements TRA and TRB. The A and B bitline structures 920A and 920B may be connected to each other in the first direction without being connected to the A and B semiconductor elements TRA and TRB. Signals transferred from the sense amplifier may be transferred to the A bitline structure 920A and the B bitline structure 920B.

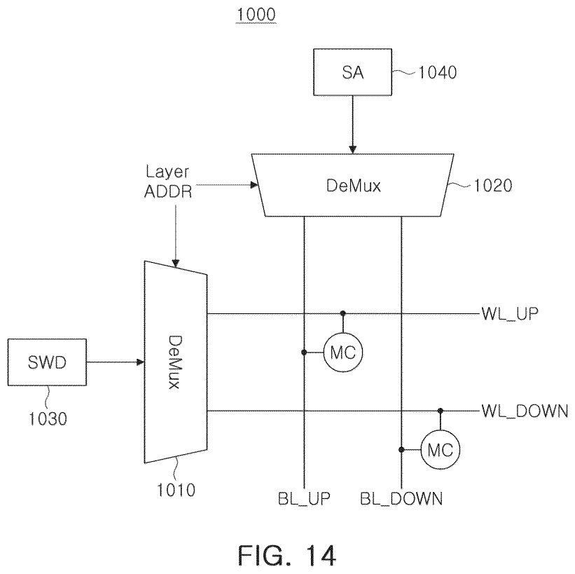

FIG. 14 is a diagram illustrating a semiconductor memory device including a demultiplexer according to an example embodiment.

In an example embodiment, the semiconductor memory device 1000 may include a plurality of sub-cell array semiconductor layers, and a core peripheral semiconductor layer. Specific example embodiments of the semiconductor memory device 1000 may be similar to the example described with reference to FIGS. 1 to 13.

The plurality of sub-cell array semiconductor layers and the core peripheral semiconductor layer may be stacked in a vertical direction in order. The sub-cell array semiconductor layer disposed in an upper portion in the vertical direction may correspond to an UP sub-cell array semiconductor layer, and the sub-cell array semiconductor layer disposed in a lower portion in the vertical direction may correspond to a DOWN sub-cell array semiconductor layer.

Each of the UP and DOWN sub-cell array semiconductor layers may include a plurality of memory cells MC disposed in matrix form. Each of the plurality of memory cells MC may be disposed at a point at which a plurality of wordlines WL and a plurality of bitlines BL intersect each other. The core peripheral semiconductor layer may include the components other than the plurality of memory cells MC, and may include the plurality of sub-wordline drivers SWD and the plurality of sense amplifiers SA.

Each of the plurality of wordlines WL included in the UP sub-cell array semiconductor layer may be vertically connected to each of the plurality of wordlines WL included in the DOWN sub-cell array semiconductor layer. In this case, a demultiplexer 1010 may be connected between the wordlines WL connected in the vertical direction. A specific example embodiment of the wordline WL connection structure may be similar to the example described with reference to FIG. 12.

The plurality of bitlines BL included in the UP sub-cell array semiconductor layer may be vertically connected to the plurality of bitlines BL included in the DOWN sub-cell array semiconductor layer, respectively. In this case, the demultiplexer 1020 may be connected between the bitlines BL connected in the vertical direction. A specific example embodiment of the bitline BL connection structure may be similar to the example described with reference to FIG. 13.

According to an example embodiment illustrated in FIG. 14, a wordline WL connected in the first direction may include an UP wordline WL_UP included in an UP sub-cell array semiconductor layer and a DOWN wordline WL_DOWN included in the DOWN sub-cell array semiconductor layer.

The UP wordline WL_UP and the DOWN wordline WL_DOWN may be connected to a demultiplexer 1010, and the demultiplexer 1010 may be connected to a sub-wordline driver 1030. In other words, the UP wordline WL_UP and the DOWN wordline WL_DOWN connected to each other in the first direction may be connected to the sub-wordline driver 1030.

According to an example embodiment illustrated in FIG. 14, the bitline BL connected in the first direction may include an UP bitline BL_UP included in the UP sub-cell array semiconductor layer and a DOWN bitline BL_DOWN included in the DOWN sub-cell array semiconductor layer. The UP bitline BL_UP and the DOWN bitline BL_DOWN may be connected to the demultiplexer 1020, and the demultiplexer 1020 may be connected to the sense amplifier 1040. In other words, the UP bitline BL_UP and the DOWN bitline BL_DOWN connected to each other in the first direction may be connected to the sense amplifier 1040.

Different layer addresses Layer ADDR may be assigned to each of the UP and DOWN sub-cell array semiconductor layers. The demultiplexer 1010 and 1020 may receive a layer address, and for example, the memory controller (120 in FIG. 2) may transmit a layer address to the demultiplexer 1010 and 1020.

When a signal is received in the demultiplexer 1010 from the sub-wordline driver 1030, the demultiplexer 1010 may activate a wordline corresponding to the layer address among the UP wordline WL_UP and the DOWN wordline WL_DOWN.

When a signal is received in the demultiplexer 1020 from the sense amplifier 1040, the demultiplexer 1020 may activate a bitline corresponding to the layer address among the UP bitline BL_UP and the DOWN bitline BL_DOWN.

In other words, a target memory cell MC for writing data or reading data may be selectively activated through the demultiplexers 1010, 1020 and the layer address. Accordingly, the speed of writing data or reading data may be improved.

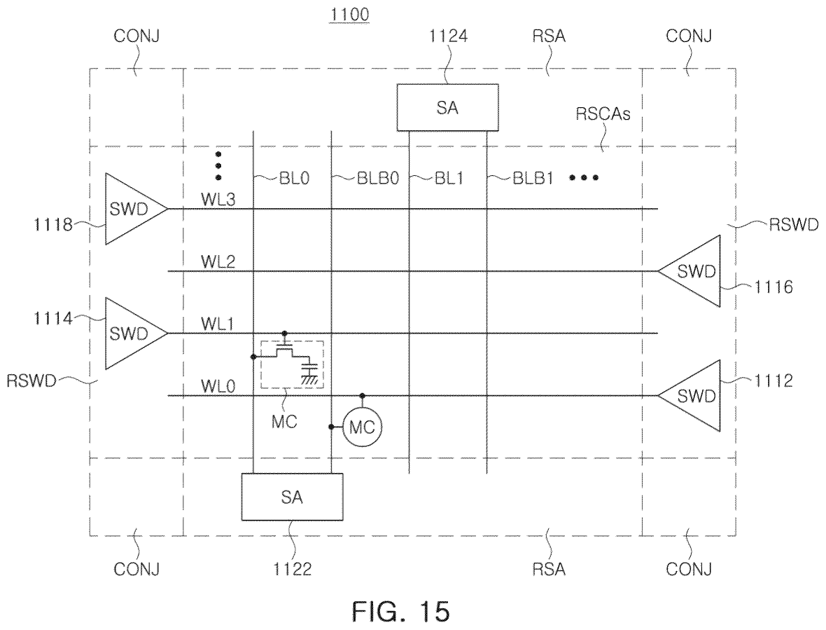

FIG. 15 is a diagram illustrating a semiconductor memory device according to an example embodiment.

The semiconductor memory device 1100 may include a plurality of sub-cell array regions RSCAs, a sub-wordline driver region RSWD and a sense amplifier region RSA. The semiconductor memory device 1100 may include a plurality of semiconductor layers. Specific example embodiments of the semiconductor memory device 1100 may be similar to the example described with reference to FIGS. 1 to 14.

The plurality of sub-cell array regions RSCAs may include a plurality of sub-cell arrays. The plurality of sub-cell arrays may include a plurality of wordlines WL0-WL3 extending in the row direction and a plurality of bitline pairs BL0-BL1, BLB0-BLB1 extending in the column direction. The plurality of sub-cell arrays may include a plurality of memory cells MC disposed at points at which a plurality of wordlines WL0-WL3 and a plurality of bitline pairs BL0-BL1, BLB0-BLB1 intersect each other.

The sub-wordline driver region RSWD may include a plurality of sub-wordline drivers 1112, 1114, 1116, and 1118. The sub-wordline driver SWD may drive each of the plurality of wordlines WL0-WL3. As an example embodiment illustrated in FIG. 7, the sub-wordline drivers 1112, 1114, 1116, and 1118 may be disposed alternately on the left and right sides of the sub-cell array region RSCA.

The sense amplifier region RSA may include a plurality of sense amplifiers 1122 and 1124 connected to bitline pairs BL1-BL2 and BLB1-BLB2. The sense amplifier SA may amplify a difference in voltage level sensed to the bitline pair BL and BLB, and may provide a difference in amplified voltage level to a local input/output line pair. As an example embodiment illustrated in FIG. 15, the plurality of sense amplifiers 1122 and 1124 may be disposed alternately above and below the sub-cell array region RSCA.

The conjunction region CONJ may be disposed adjacent to the sub-wordline driver region RSWD and the sense amplifier region RSA. The conjunction region CONJ may include a plurality of wordline driving signal generator circuits.

Referring to FIG. 4 together, the sub-wordline driver region RSWD and the sense amplifier region RSA may be included in a core peripheral semiconductor layer CP_LA, which is a single semiconductor layer. A plurality of sub-cell array regions RSCAs may be isolated from each other and may be included in the first and second sub-cell array semiconductor layers SCA_LA1 and SCA_LA2.

According to an example embodiment, the plurality of semiconductor layers may be stacked in the first direction (Z-axis direction in FIG. 4) and may physically and electrically connected to each other in the first direction. Accordingly, the wordline WL may be formed in the first and second sub-cell array semiconductor layers SCA_LA1 and SCA_LA2, and the bitline pair BL and BLB may also be formed in the first and second sub-cell array semiconductor layers SCA_LA1 and SCA_LA2.

In an example embodiment, in a 0th wordline WL0, the section from one end of the 0th wordline WL0 to a point intersecting the 0th bitline pair BL0 and BLB0 and the section from the point intersecting the first bitline pair BL1, BLB1 to the other end of the 0th wordline WL0 may be formed in different sub-cell array semiconductor layers.

In the 0th wordline WL0, the section from one end of the 0th wordline WL0 to the point intersecting the mth bitline pair BLm and BLBm and the section from the point intersecting the mth+1 bitline pair BLm+1 and BLBm+1 to the other end of the 0th wordline WL0 may be formed in different sub-cell array semiconductor layers.

In the 0th bitline pair BL0 and BLB0, the section from one end of each of the 0th bitline pair BL0 and BLB0 to the point intersecting the mth wordline WLm and the section from the point intersecting the mth+1 wordline WLm+1 to the other end of each of the 0th bitline pair BL0 and BLB0 may be formed in different sub-cell array semiconductor layers.

By increasing the number of plurality of memory cells MC connected to the same core peripheral semiconductor layer CP_LA by increasing the number of sub-cell array semiconductor layers SCA_LA stacked in the first direction, integration density of the semiconductor memory device 1100 may be improved. Alternatively, by reducing the core peripheral semiconductor layer CP_LA and vertically stacking the plurality of memory cells MC by isolating the plurality of memory cells MC into a plurality of sub-cell array semiconductor layers SCA_LA, integration density of the semiconductor memory device 1100 may be improved.

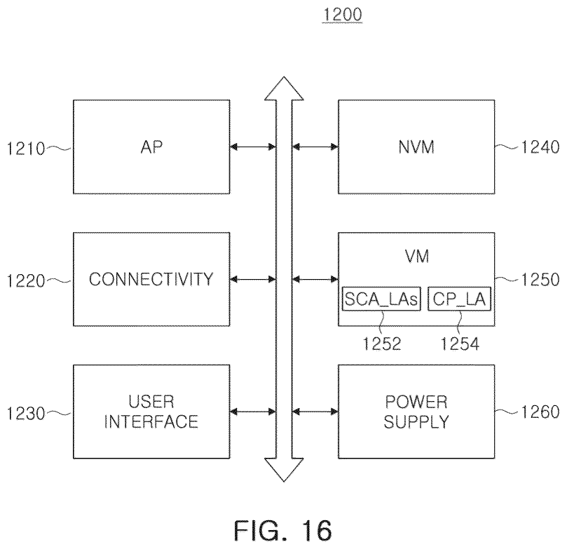

FIG. 16 is a diagram illustrating an example in which a semiconductor memory device is applied to a mobile system according to an example embodiment.

Referring to FIG. 16, a mobile system 1200 may include an application processor 1210, a connectivity portion 1220, a user interface 1230, a nonvolatile memory device 1240, a volatile memory device 1250, and a power supply 1260. The application processor 1210 may include a memory controller.

The mobile system 1200 may be implemented as a mobile system, such as a mobile phone, a smart phone, a personal digital assistant (PDA), a portable multimedia player (PMP), a digital camera, a music player, a portable game console, a navigation system, or the like.

The application processor 1210 may execute applications providing an Internet browser, a game, a video, or the like. The connectivity portion 1220 may perform wireless or wired communication with an external device. The user interface 1230 may include one or more input devices, such as a keypad and a touch screen, and/or one or more output devices, such as a speaker and a display device.

The nonvolatile memory device 1240 may store a boot image for booting the mobile system 1200.

The volatile memory device 1250 may store data processed by the application processor 1210 or may operate as a working memory. According to an example embodiment, the volatile memory device 1250 may include a plurality of sub-cell array semiconductor layers 1252 and a core peripheral semiconductor layer 1254.

The plurality of sub-cell array semiconductor layers 1252 and the core peripheral semiconductor layer 1254 may be stacked in the vertical direction. The plurality of sub-cell array semiconductor layers 1252 and the core peripheral semiconductor layer 1254 may be physically and/or electrically connected to each other in the vertical direction.

The number of the plurality of sub-cell array semiconductor layers 1252 may be increased. In other words, the number of the plurality of memory cells connected to the core peripheral semiconductor layer 1254 may be increased, thereby improving integration density of the volatile memory device 1250.

The power supply 1260 may supply an operation voltage of the mobile system 1200. The mobile system 1200 or components of the mobile system 1200 may be mounted using various types of packages.

According to the aforementioned example embodiments, by connecting the plurality of wordlines included in the plurality of semiconductor layers stacked in the vertical direction to each other and connecting the plurality of bitlines to each other in the vertical direction, density of the semiconductor layers may be improved, thereby improving integration density of the dynamic random access memory.

While the example embodiments have been illustrated and described above, it will be configured as apparent to those skilled in the art that modifications and variations could be made without departing from the scope of the present disclosure as defined by the appended claims.

What is claimed is:

1. A semiconductor memory device comprising:
a first semiconductor layer comprising at least one first sub-cell array, the at least one first sub-cell array comprising a plurality of memory cells;
a second semiconductor layer comprising at least one second sub-cell array; and
a third semiconductor layer comprising a plurality of sub-wordline drivers and a plurality of sense amplifiers,
wherein the first, the second, and the third semiconductor layers are stacked in a first direction perpendicular to an upper surface of the first semiconductor layer,
wherein the first semiconductor layer comprises a plurality of first wordlines extending in a direction perpendicular to the first direction and a plurality of first bitlines extending in the direction perpendicular to the first direction,
wherein the second semiconductor layer comprises a plurality of second wordlines extending in the direction perpendicular to the first direction and a plurality of second bitlines extending in the direction perpendicular to the first direction,
wherein the plurality of first wordlines are connected to the plurality of second wordlines in the first direction,
wherein each of the plurality of first wordlines is connected to one of the plurality of sub-wordline drivers,
wherein the plurality of first bitlines are connected to the plurality of second bitlines in the first direction, and
wherein each of the plurality of first bitlines is connected to one of the plurality of sense amplifiers.

2. The semiconductor memory device of claim 1, wherein the first and the second semiconductor layers are stacked on the third semiconductor layer.

3. The semiconductor memory device of claim 1, wherein the third semiconductor layer is stacked on the first and the second semiconductor layers.

4. The semiconductor memory device of claim 1, wherein a number of sub-cells in the at least one first sub-cell array is the same as a number of sub-cells in the at least one second sub-cell array.

5. The semiconductor memory device of claim 4, wherein a size of the at least one first sub-cell array is the same as a size of the at least one second sub-cell array.

6. The semiconductor memory device of claim 1, wherein sizes of the first, the second, and the third semiconductor layers are the same.

7. The semiconductor memory device of claim 1, wherein the plurality of first wordlines and the plurality of second wordlines extend in a second direction parallel to the upper surface of the first semiconductor layer, and
wherein the plurality of first bitlines and the plurality of second bitlines extend in a third direction parallel to the upper surface of the first semiconductor layer and perpendicular to the second direction.

8. The semiconductor memory device of claim 7, wherein the plurality of first wordlines overlap the plurality of second wordlines in the first direction, and
wherein the plurality of first bitlines overlap the plurality of second bitlines in the first direction.

9. The semiconductor memory device of claim 1, wherein a first layer address is assigned to the first semiconductor layer and a second layer address, different from the first layer address, is assigned to the second semiconductor layer.

10. A semiconductor memory device comprising:
a first region comprising a plurality of first sub-cell arrays;
a second region comprising a plurality of second sub-cell arrays; and
a third region comprising a plurality of third sub-regions,
wherein each of the plurality of third sub-regions comprises:
a sub-wordline driver region comprising a plurality of sub-wordline drivers; and
a sense amplifier region comprising a plurality of sense amplifiers,
wherein the first, the second, and the third regions are stacked in a first direction,
wherein each of the plurality of first sub-cell arrays comprises a plurality of first wordlines extending in a second direction perpendicular to the first direction and a plurality of first bitlines extending in a third direction perpendicular to the first direction and the second direction,
wherein each of the plurality of second sub-cell arrays comprises a plurality of second wordlines extending in the second direction and a plurality of second bitlines extending in the third direction,
wherein, for each first sub-cell array of the plurality of first sub-cell arrays, the plurality of first wordlines are connected in the first direction to the plurality of second wordlines of a second sub-cell array among the plurality of second sub-cell arrays,
wherein, for each first sub-cell array of the plurality of first sub-cell arrays, the plurality of first wordlines are connected to the sub-wordline driver region of a third sub-region among the plurality of third sub-regions,
wherein, for each first sub-cell array of the plurality of first sub-cell arrays, the plurality of first bitlines are connected in the first direction to the plurality of second bitlines of a second sub-cell array among the plurality of second sub-cell arrays, and
wherein, for each first sub-cell array of the plurality of first sub-cell arrays, the plurality of first bitlines are connected to the sense amplifier region of a third sub-region among the plurality of third sub-regions.

11. The semiconductor memory device of claim 10, wherein the third region is stacked on the first and the second regions, or is below the first and the second regions.

12. The semiconductor memory device of claim 10, wherein a number of the plurality of first sub-cell arrays, a number of the plurality of second sub-cell arrays, and a number of the plurality of third sub-regions are the same.

13. The semiconductor memory device of claim 10, wherein a size of a first sub-cell array among the plurality of first sub-cell arrays, a size of a second sub-cell array among the plurality of second sub-cell arrays, and a size of a third sub-region among the plurality of third sub-regions are the same.

14. The semiconductor memory device of claim 10,
wherein, for each first sub-cell array of the plurality of first sub-cell arrays, each of the plurality of first wordlines is connected to one of the plurality of sub-wordline drivers of the sub-wordline driver region to which the plurality of first wordlines is connected, and
wherein, for each first sub-cell array of the plurality of first sub-cell arrays, each of the plurality of first bitlines is connected to one of the plurality of sense amplifiers of the sense amplifier region to which the plurality of first bitlines is connected.

15. The semiconductor memory device of claim 10, wherein an arrangement of the plurality of first sub-cell arrays, an arrangement of the plurality of second sub-cell arrays, and an arrangement of the plurality of third sub-regions are the same.

16. The semiconductor memory device of claim 15, wherein the plurality of first sub-cell arrays, the plurality of second sub-cell arrays, and the plurality of third sub-regions are arranged in matrix form.

17. The semiconductor memory device of claim 16, wherein in each of the plurality of third sub-regions, the sub-wordline driver region and the sense amplifier region are disposed in the second direction.

18. The semiconductor memory device of claim 10, wherein the plurality of first sub-cell arrays, the plurality of second sub-cell arrays, and the plurality of third sub-regions overlap each other in the first direction.

19. The semiconductor memory device of claim 10, wherein a first layer address is assigned to the first region and a second layer address, different from the first layer address, is assigned to the second region.

20. A semiconductor memory device comprising:
a first semiconductor layer comprising a plurality of first wordlines and a plurality of first bitlines;
a second semiconductor layer comprising a plurality of second wordlines and a plurality of second bitlines;
a third semiconductor layer comprising a plurality of sub-wordline drivers and a plurality of sense amplifiers;
a plurality of interconnection patterns extending in a first direction perpendicular to an upper surface of the first semiconductor layer; and
a plurality of bonding pads on an upper surface or a lower surface of one of the first, the second, and the third semiconductor layers,
wherein the first, the second, and the third semiconductor layers are stacked in the first direction and are coupled to each other by the plurality of bonding pads,
wherein the plurality of first wordlines and the plurality of second wordlines extend in a second direction parallel to the upper surface of the first semiconductor layer and perpendicular to the first direction,
wherein the plurality of first bitlines and the plurality of second bitlines extend in a third direction parallel to the upper surface of the first semiconductor layer and perpendicular to the second direction,
wherein the plurality of interconnection patterns and the plurality of bonding pads connect the plurality of first wordlines to the plurality of second wordlines in the first direction, and to the plurality of sub-wordline drivers, and
wherein the plurality of interconnection patterns and the plurality of bonding pads connect the plurality of first bitlines to the plurality of second bitlines in the first direction, and to the plurality of sense amplifiers.
